(19) United States
(12) Patent Application Publication
(10) Pub. No.: US 2016/0062239 A1
(43) Pub. Date: Mar. 3, 2016

(54) METHOD FOR FABRICATING AT LEAST ONE APERTURE WITH SHAPED SIDEWALLS IN A LAYER OF A LIGHT SENSITIVE PHOTOPOLYMER

(71) Applicant: University of Southampton, Southampton (GB)

(72) Inventors: Hywel Morgan, Hampshire (GB); Sumit Kalsi, Southampton (GB); Maurits de Planque, Southampton (GB); Kian Shen Kiang, Southampton (GB)

(21) Appl. No.: 14/713,551

(22) Filed: May 15, 2015

(30) Foreign Application Priority Data
May 19, 2014 (GB) 1408911.4

(51) Int. Cl. G03F 7/20; G03F 7/16

(52) U.S. Cl. CPC G03F 7/20; G03F 7/168

(57) ABSTRACT

A method for fabricating at least one aperture (60, 64) with shaped sidewalls in a layer (52) of a light sensitive photopolymer (54), which method comprises:
(i) providing the layer (52) of the photopolymer (54);
(ii) providing a mask (56);
(iii) exposing the photopolymer (54) to light (58);
(iv) utilising the mask (56) to control the intensity of the light (58) falling on the photopolymer (54); and
(v) forming the mask (56) such that its control of the intensity of the light (58) falling on the photopolymer (54) causes the aperture (60, 64) to have the shaped sidewalls.

This invention relates to a method for fabricating at least one aperture with shaped sidewalls. More especially this invention relates to a method for fabricating at least one aperture with shaped sidewalks in a layer of a light sensitive photopolymer, for example a light sensitive photoresist.

Lipid bilayers surround all cells and bacteria. The lipid bilayers act as supports for membrane proteins. The membrane proteins are important for functions such as signalling, and molecular and ion transport. The signalling is achieved by means of action potentials. Characterisation of membrane proteins is important for drug testing and discovery. Artificial lipid bilayers have helped considerably in the understanding of membrane and protein biophysics.

One widely used artificial lipid bilayer platform is the aperture-suspended bilayer lipid membrane. These bilayer lipid membranes are conventionally suspended across apertures, and they are formed from a lipid solution in a non-polar solvent such for example as decane [Mueller et al 1962]. The lipid solution is painted across the aperture separating two aqueous compartments, wherein a bilayer is formed as the solvent drains away. The bilayer lipid membranes can also be made by a method in which lipid monolayers on the surface of water or a buffer are raised on either side of an aperture to form a bilayer lipid membrane across the aperture. Such a method is known as the Montal-Mueller method [Montal and Mueller 1972]. The formation of a stable bilayer lipid membrane requires that the aperture is made in a hydrophobic support material such as polytetrafluoethylene [Montal and Mueller 1972]. It is also known that the formed aperture should be approximately 10-500 μm in diameter and made in a material having a thickness ranging from 10-500 μm. The aperture is usually made using methods such as mechanical drilling, laser drilling, or spark discharge. More than one aperture may be formed as may be desired.

Bilayer lipid membranes are usually fragile and have short life-times. However they can be made more stable by using small diameter apertures, for example of not more than 30 μm or of having diameters of hundreds of nanometers. However, apertures of such small diameters make it difficult to insert membrane proteins into the artificial lipid bilayer lipid membrane.

Large-area stable bilayer lipid membranes can be formed using low aspect ratio apertures, i.e. the ratio of thickness of hydrophobic supporting substrate to aperture diameter [White 1972]. However, this necessitates the use of a very thin substrate as the support material, and this increases the intrinsic capacitance of the substrate and thus, the noise in electrical recordings [Wonderlin 1990], limiting their use for electrical studies of membrane proteins (known as electrophysiological recording). It also makes the entire structure much more difficult to handle, and mechanically very fragile. A solution to these problems is to use apertures having tapered sidewalls. Shaping the aperture permits the use of a thicker substrate, which significantly improves the electrical noise characteristics, and also the mechanical strength of the entire structure. Shaped apertures also dramatically increase the ease with which the artificial lipid bilayer lipid membranes can be made, and also significantly improves the stability of the bilayer lipid membranes due to the low aspect ratio of the substrate at the tip [Eray et al 1994, Iwata et al 2010, Oshima et al 2012, and USA Patent Publication No. 2012114925 A1]. However, all the known methods described in the literature of fabricating tapered apertures suffer from disadvantages. For example, silicon or silicon nitride substrates have been used, but fabrication with these materials requires expensive and time consuming lithography and etching. Silicon based systems also produce high intrinsic electrical noise. Shaped apertures can be made in extremely thin photopolymers [Eray el al 1994] but this necessitates the use of an extra support material. Other known methods require a multi-mask fabrication process to manufacture the tapered aperture in photoresists. More specifically, numerous single masks are used, each of which has to be aligned with the other masks, and to the layers of photoresist. Multiple separate exposure steps are used, making the manufacture process long and drawn out. Maskless direct write lithography techniques such as electron beam lithography, focussed ion beam, two photon lithography or laser lithography can also be used to fabricate shaped apertures. Two photon lithographic methods have been used to manufacture shaped apertures in a negative tone photoresist known as SU8 (Kalsi et al. 2014). In this method, a focussed beam of light is raster scanned across a surface to cross link the photoresist to different degrees. However, such an approach is very time consuming and only a single aperture can be made in a period of approximately thirteen hours.

It is an aim of the present invention to reduce the above mentioned problems.

Accordingly, in one non-limiting embodiment of the present invention there is provided a method for fabricating at least one aperture with shaped sidewalls in a layer of a light sensitive photopolymer, which method comprises:
(i) providing the layer of the photopolymer;
(ii) providing a mask;
(iii) exposing the photopolymer to light;
(iv) utilising the mask to control the intensity of the light falling on the photopolymer; and
(v) forming the mask such that its control of the intensity of the light falling on the photopolymer causes the aperture to have the shaped sidewalls.

In the method of the present invention, varying the intensity of the light incident on the photopolymer leads to changes in the cross linking of the photopolymer, permitting the required shape for the aperture to be fabricated. Exposing the photopolymer through the mask enables the production of a pseudo three dimensional shape in a single step. The photopolymer is able to provide one or a plurality of the apertures in a single step exposure process. Furthermore, the aperture or apertures are able to be provided within a short period of time of a few minutes, for example 3-6 minutes.

The method of the invention may be one in which the mask is a grey scale mask having grey levels, and in which a required shape for the aperture is encoded in the grey levels of the grey scale mask. As a result of localised modulation of light intensity by grey levels on the mask, a variable light intensity across the photopolymer surface is obtained which gives multiple depths of exposed photopolymers, and thus different photopolymer heights after development of the photopolymer. The mask can be either a pixelated or continuous tone mask. Pixelated masks may be binary chrome masks with different densities of opaque pixels that are below the resolution of the photolithography tool, on a transparent support such as quartz. Continuous tone masks have a continuous variation of optical intensity and comprise generally a high-energy-beam sensitive glass to simulate different grey levels.

Alternatively, the method of the invention may be one in which the mask may be a software mask, and in which a required shape for the aperture is defined by the software in the software mask. The software mask may employ digital mirror device technology which consists of an array of micro-mirrors that can be rapidly configured by software to control the amount of time a micro-mirror reflects light onto the photopolymer. The varying amount of light governs the exposure dose and thus creates 3D features in the depth of exposed photopolymer.

The method of the present invention may be one in which the photopolymer hardens when exposed to the light. Such a photopolymer may be, for example, a negative photoresist. The negative photoresist may be a liquid negative photoresist such for example as SU8, or it may be a solid laminate sheet negative photoresist such for example as TMMF. The liquid negative photoresist may be a liquid solvent-based negative photoresist. Other types of photopolymer that harden on light exposure may be employed. The negative photoresist is typically an epoxy based material and contains a photo-acid which upon exposure to light catalyses the cross-linking of the epoxide groups, hardening the material. Unexposed photoresist can be washed away with solvents. The degree of cross linking of the photopolymer depends in some manner on the amount of light falling on the material.

Alternatively, the method of the present invention may be one in which the photopolymer is one which weakens or becomes dissolvable after exposure to the light. The photopolymer may become dissolvable or more dissolvable in a developer. The photopolymer may be, for example, a positive photoresist. The polymer chains of the photopolymer are broken by the light, allowing these to be dissolved away after processing the material.

The photopolymer which weakens or becomes dissolvable after exposure to the light may be a liquid photopolymer or a solid laminate sheet photopolymer. Other types of photopolymer that are broken by the light may be employed.

The method of the invention may be one in which the photopolymer is an unsupported photopolymer. After exposure, development and baking, the photopolymer may become a hard film with excellent mechanical and physical-chemical properties. The fabricated hard films do not require any further support material. However, if desired, further support material may be provided.

The method of the invention may alternatively be one which includes providing a substrate as a support for the photopolymer, and providing the photopolymer on the substrate.

The method of the invention may include exposing the photopolymer to the light from the side of the photopolymer that is remote from the substrate. In this case, the substrate may be a transparent substrate, an optically opaque substrate, or an absorbent substrate. Any suitable and appropriate substrate such as the ones used in a standard lithographic process may be employed for this top side exposure.

Alternatively, the method of the invention may be one which includes exposing the photopolymer to the light through the substrate, and in which the substrate is to be an optically transparent substrate. The optically transparent substrate may be a glass substrate. Other optically transparent substrates may be employed.

Generally, exposure from the topside may yield an aperture having a cross sectional shape which is beak-shaped or hour-glass shaped. The exposure from the substrate side may provide an aperture which has a cross section which is triangular in shape. Apertures having other cross sectional shapes may be produced.

The method of the present invention may include treating the surface of the photopolymer to make the surface of the photopolymer more hydrophobic.

The treating of the surface of the photopolymer may comprise depositing a thin layer of parylene using vapour deposition. The thin layer of parylene may be not more than 500 nm thick. Alternatively, the treating may comprise spin coating or dip coating Cytop or Teflon AF. In this case, the coating may be not more than 100 nm thick. Alternatively, the treating may comprise a carbon tetrafluoride plasma treatment. Alternatively, the treating may comprise a hydrophobic silane treatment.

The method of the present invention may comprise forming a bilayer lipid membrane across the aperture.

The bilayer lipid membrane may be clamped between two chambers of a friction reducing material. The friction reducing material may be Teflon (Registered Trade Mark).

The method may be one in which the two chambers have compartments, in which the compartments are filled with a buffer solution, and in which the bilayer lipid membrane is formed using a painting method. The painting method may comprise placing 2-5 μl of lipid and non-polar solvent suspension on a paintbrush, and moving the paintbrush across the aperture to form the bilayer lipid membrane.

Alternatively, the method may be one in which the two chambers have compartments, in which the compartments are filled with a buffer solution, and in which the bilayer lipid membrane is formed using a Montal-Mueller method. The Montal-Mueller method may comprise pre-treating the aperture with 5% volume/volume hexadecane in hexane, placing 5-10 μl of a lipid in a volatile solvent on top of the buffer, allowing the solvent to evaporate for twenty—thirty minutes to give lipid monolayers on top of the buffer, and raising and lowering the buffer to cause the bilayer lipid membrane to be formed over the aperture.

In the various methods of producing the bilayer lipid membrane, proteins and/or peptides ion channels may be incorporated into the bilayer lipid membrane.

In all embodiments of the invention, the light sensitive photopolymer is preferably a light sensitive photoresist. The light sensitive photopolymer may be an ultraviolet light sensitive photopolymer such as for example SU8 or TMMF which are negative tone resists, AZ series of resists, HD series or SPR series of resists. Other light sensitive photopolymers may be employed such for example as chemically amplified photopolymers having a preferred sensitizer of 1,4-diethoxy-9,10-bisphenylethynylanthracene that can be crosslinked with visible light [U.S. Pat. No. 7,807,340 B2]. The light may be ultraviolet light or other suitable light.

Embodiments of the invention will now be described solely by way of example and with reference to the accompanying drawings in which:

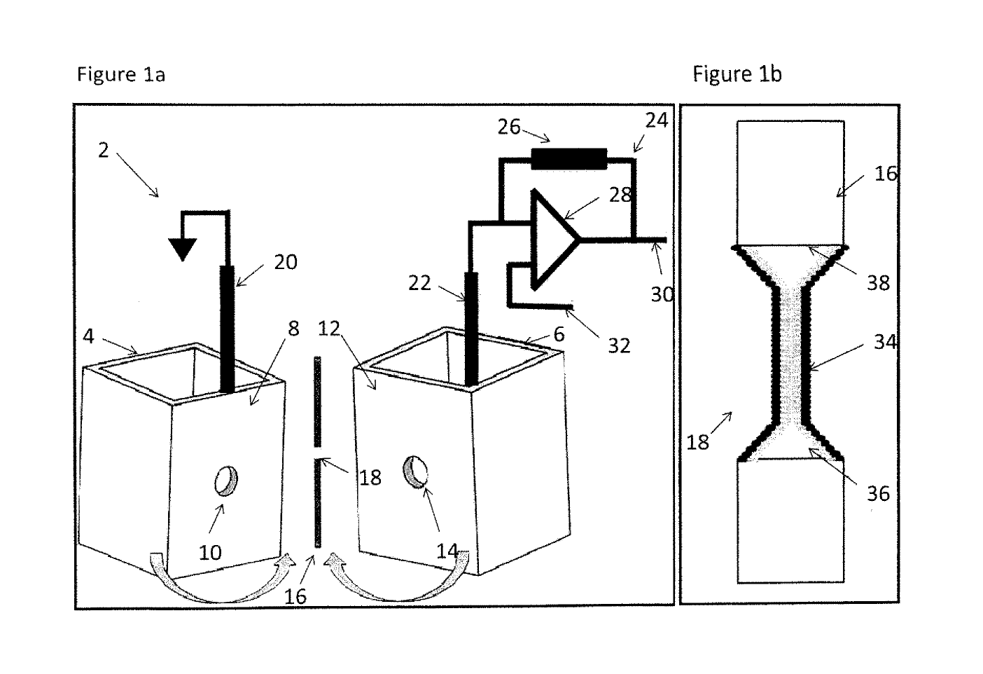

FIG. 1a shows known apparatus for the conventional formation of bilayer lipid membranes, where the bilayer lipid membranes are formed from a lipid solution painted across an aperture separating two aqueous compartments;

FIG. 1b is an enlarged cross section through a bilayer lipid membrane shown in FIG. 1a;

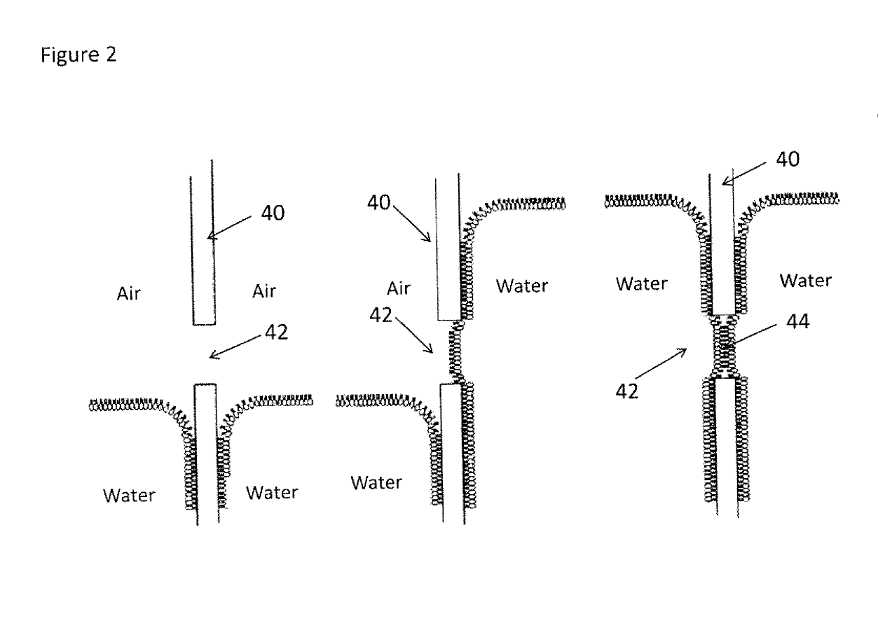

FIG. 2 is a schematic diagram showing the formation of a bilayer lipid membrane using a known Montal-Mueller method (Figure taken from A J Williams 1994);

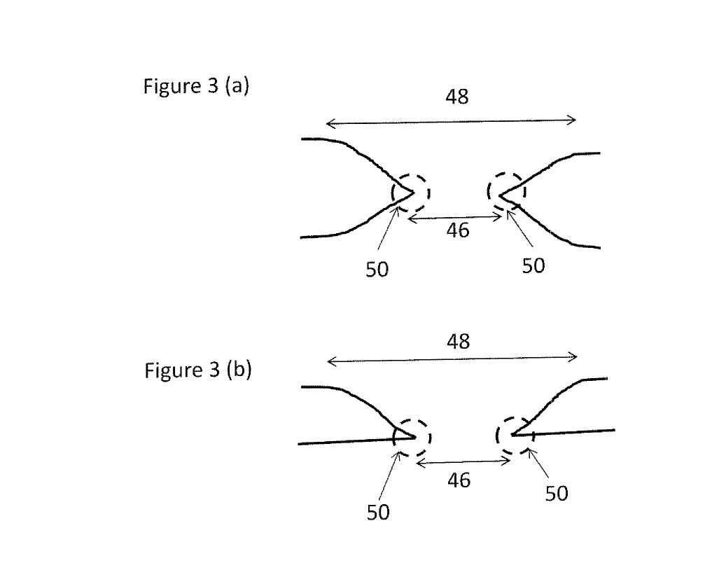

FIG. 3a shows a known aperture with a shaped sidewall, the aperture having a beak-shaped cross section;

FIG. 3b shows a known aperture with a shaped sidewall, the aperture having a triangular-shaped cross section;

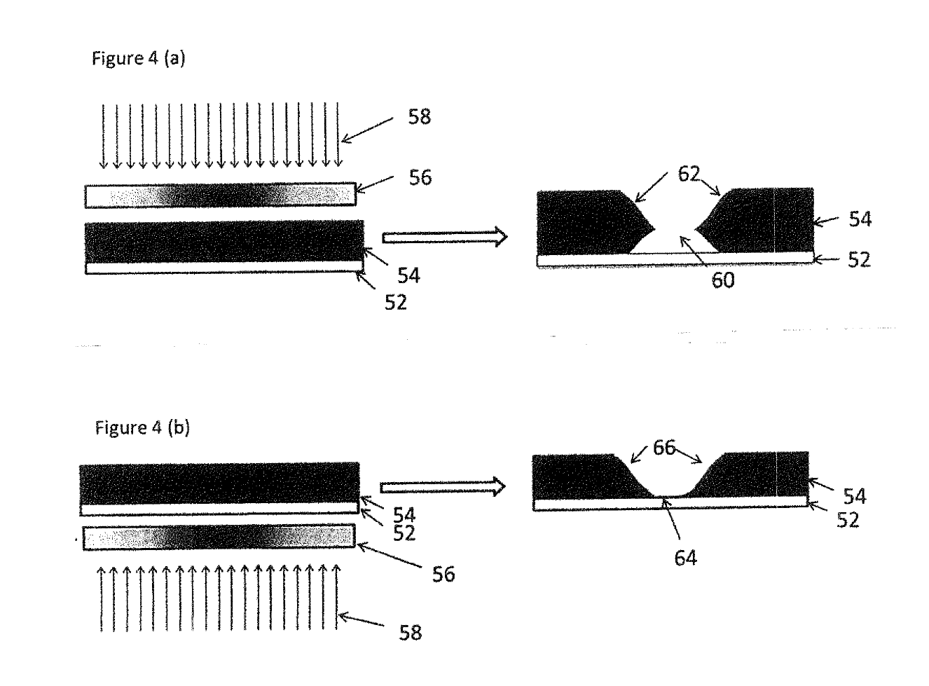

FIGS. 4a and 4b illustrate two ways according to the method of the present invention of fabricating an aperture with shaped sidewalls in a layer of an ultraviolet sensitive negative tone photoresist;

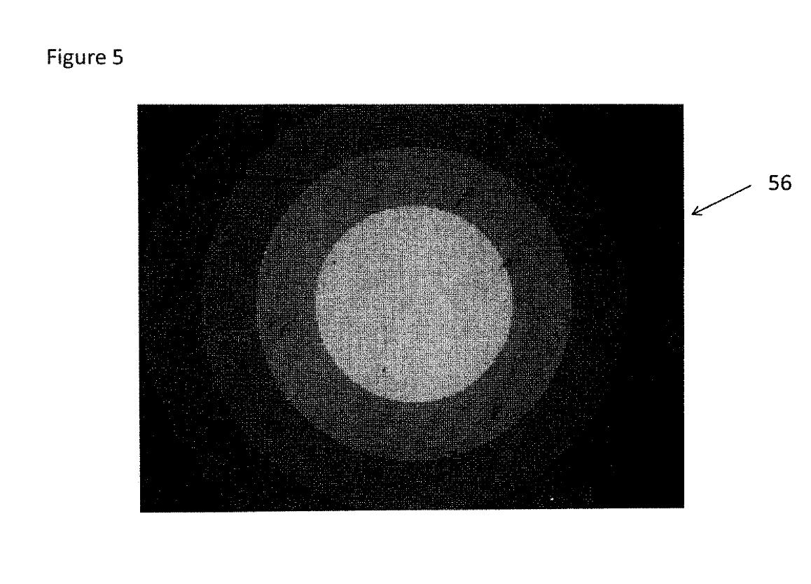

FIG. 5 is a microscopic image of a pixelated grey scale mask;

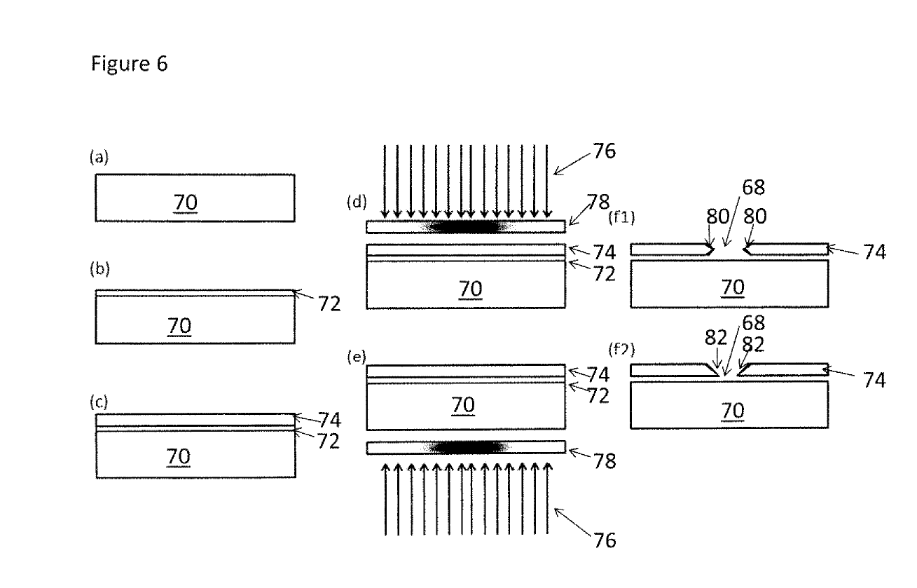

FIG. 6 shows the steps for a first method of the present invention and using a negative tone resist;

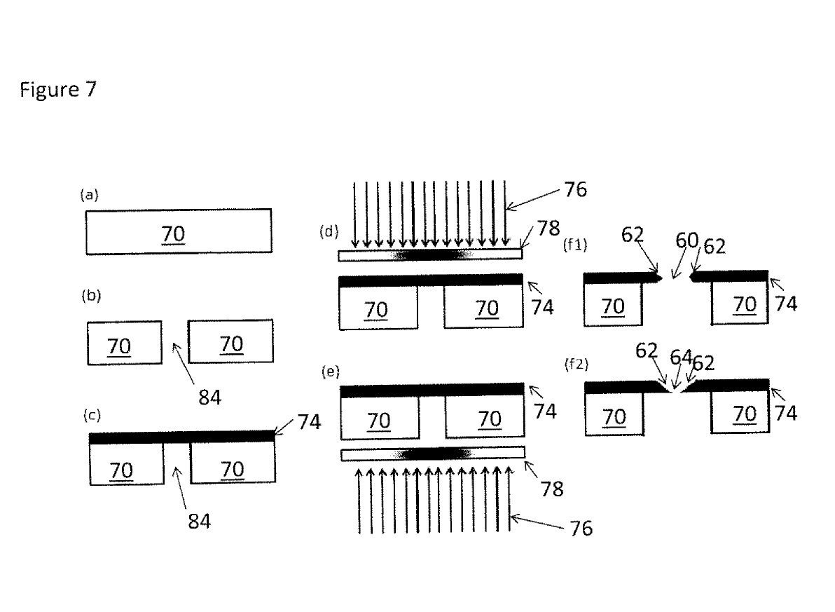

FIG. 7 shows the steps for a second method of the present invention and using a negative tone resist;

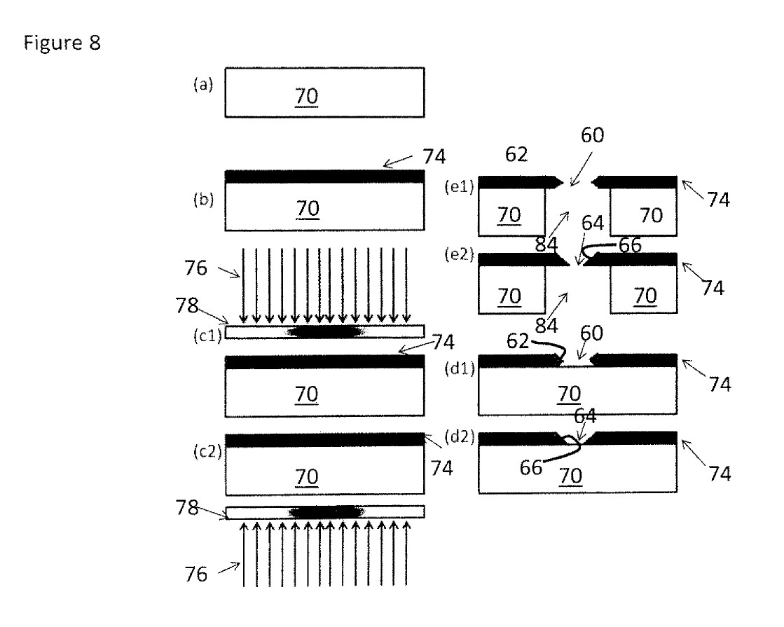

FIG. 8 shows a third method of the present invention and using a negative tone resist;

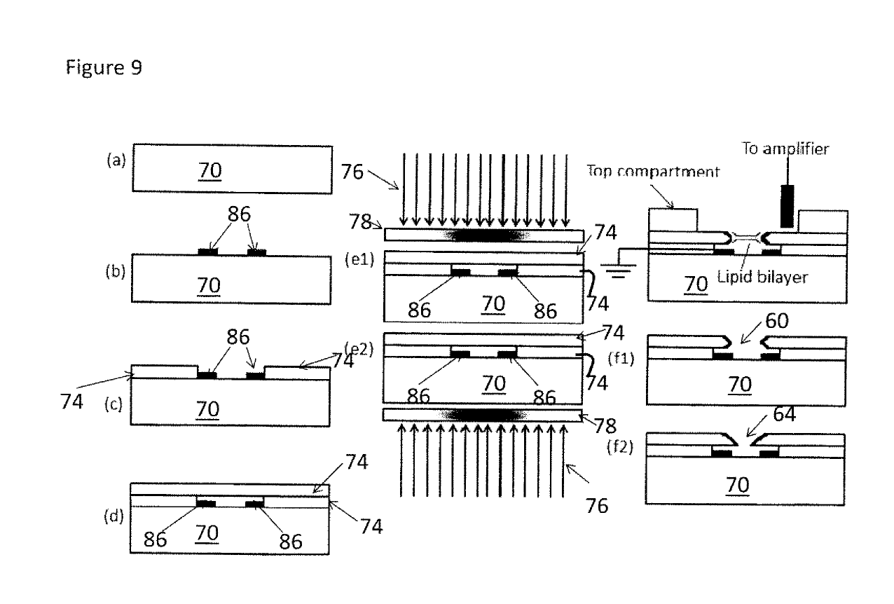

FIG. 9 shows a fourth method of the present invention and using a negative tone resist;

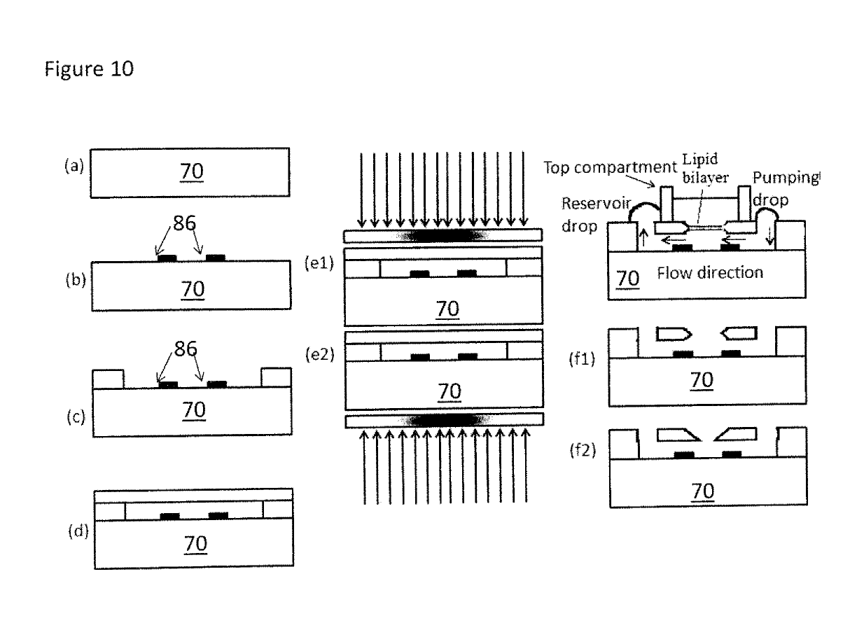

FIG. 10 shows a fifth method of the present invention and using a negative tone resist;

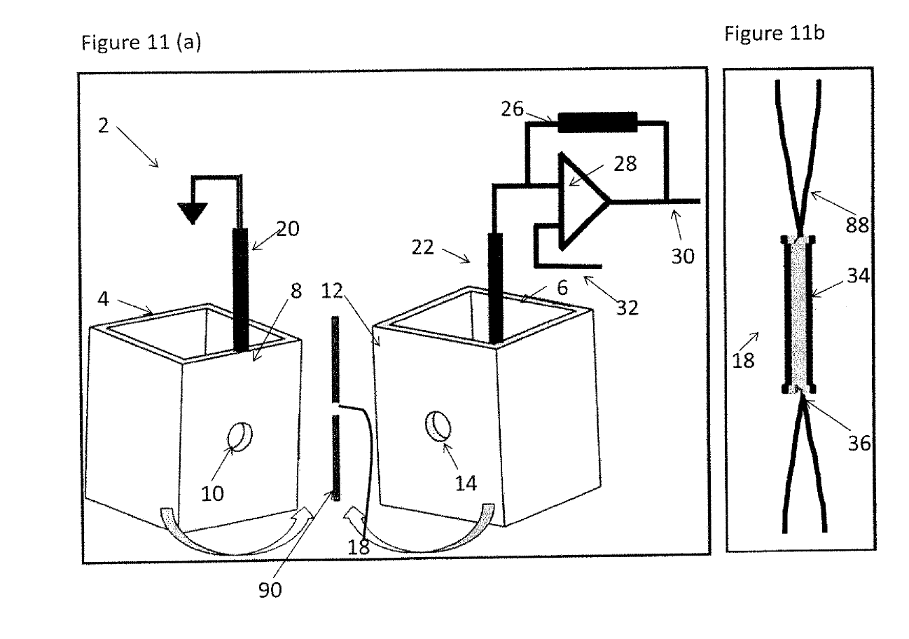

FIG. 11a shows apparatus for carrying out a sixth method of the present invention and using a sheet of photoresist with a shaped aperture;

FIG. 11b is an enlarged cross section through a bilayer lipid membrane shown in FIG. 11a;

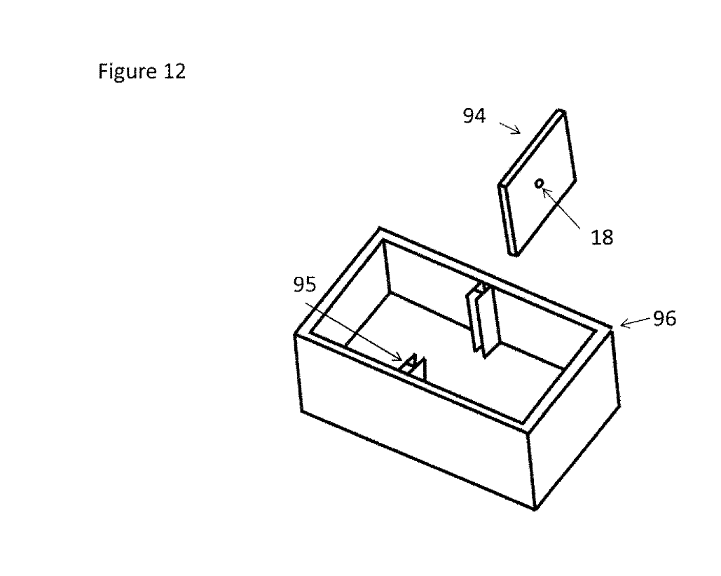

FIG. 12 illustrates the use of a photoresist sheet with a shaped aperture attached to a substrate;

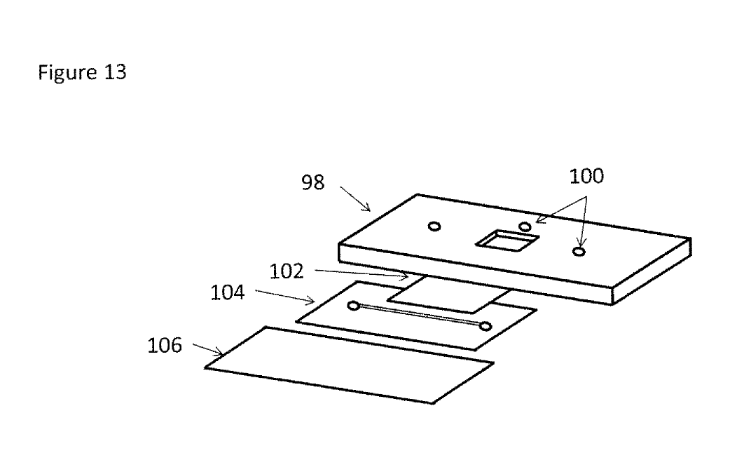

FIG. 13 shows the use of photoresist sheets in a microfluidic chip;

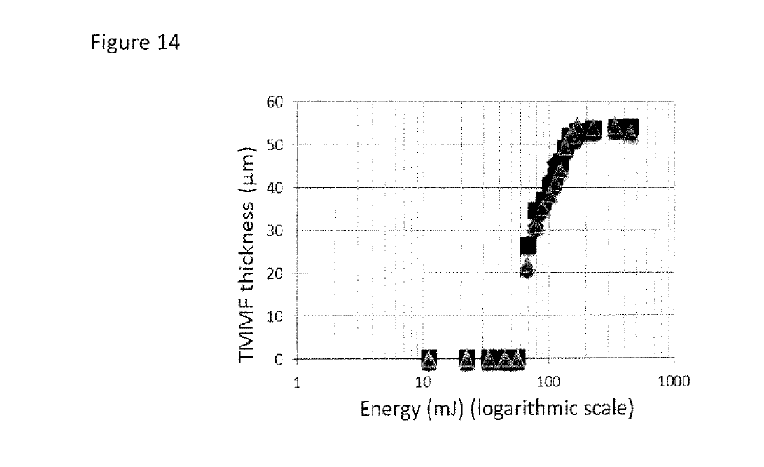

FIG. 14 shows variations in the height of negative tone resist, TMMF, with energy dose for three independent experiments;

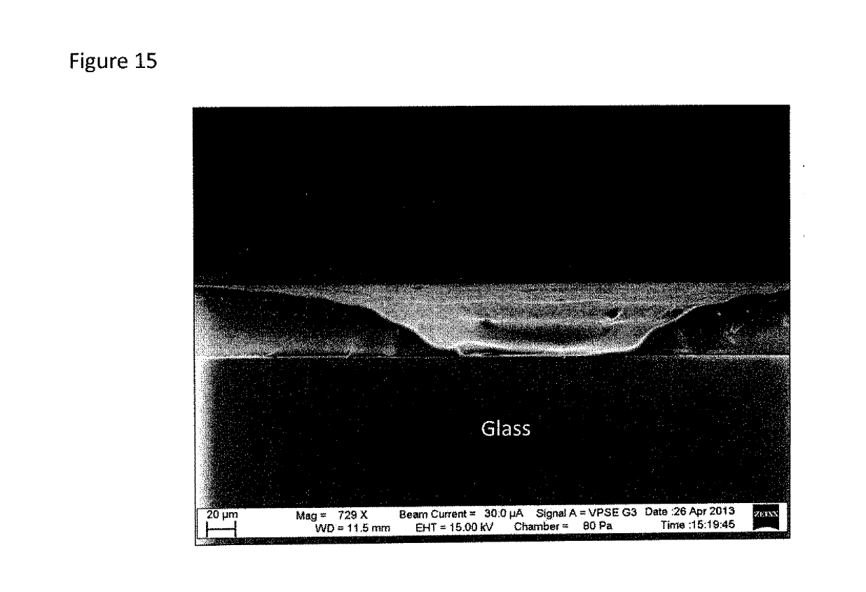

FIG. 15 is an scanning electron microscope (SEM) of a triangle-shaped aperture in TMMF using greyscale lithography;

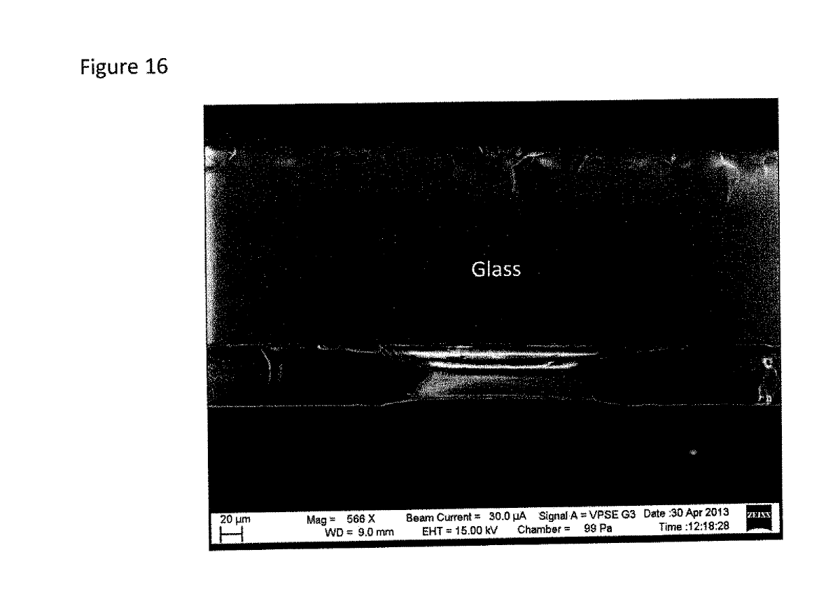

FIG. 16 is an SEM of a beak-shaped aperture in TMMF using greyscale lithography;

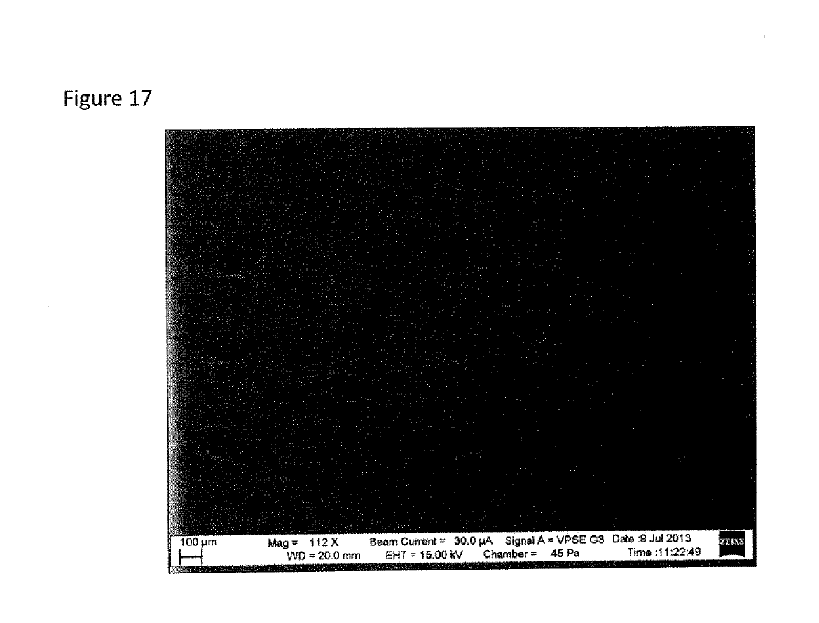

FIG. 17 is a SEM of a 3×3 array of beak-shaped apertures in TMMF greyscale lithography;

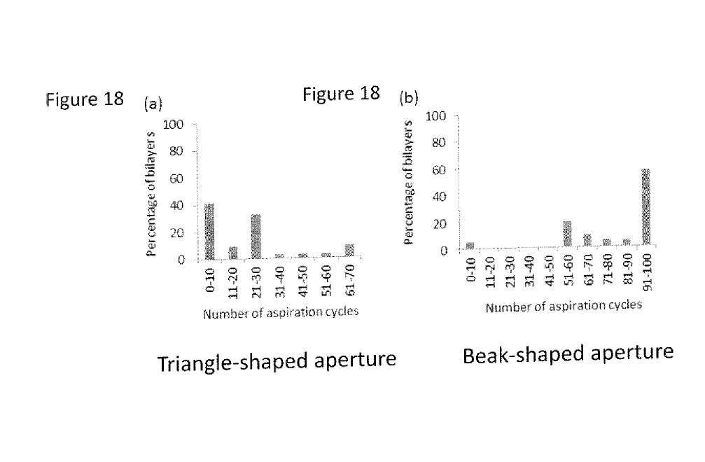

FIGS. 18a and 18b illustrate the stability of a vertical DOPE:POPG (1:1 molar ratio) lipid bilayer membrane formed in shaped apertures fabricated using a grayscale mask, with a Montal-Mueller method to aspiration cycles;

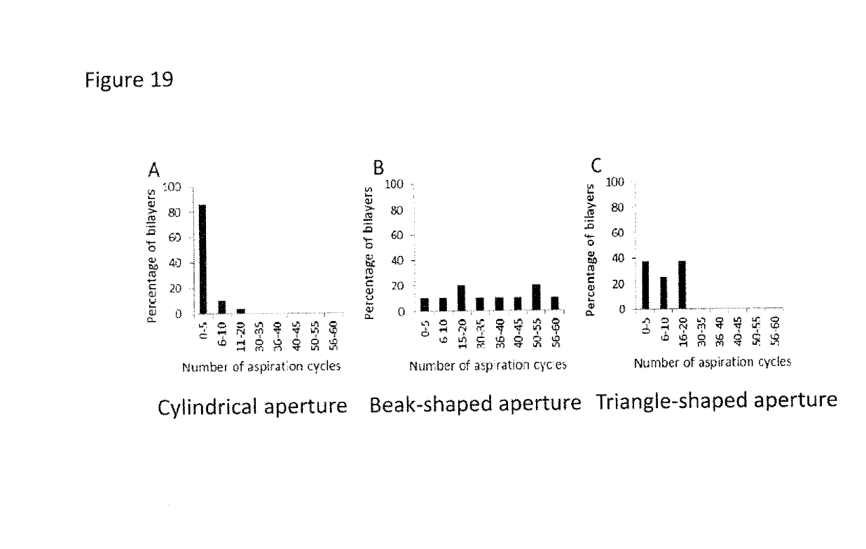

FIGS. 19b and 19c illustrate the stability of DOPC:POPG (1:1 molar ratio) bilayer lipid membrane to aspiration cycles in apertures fabricated with two photon polymerization; and

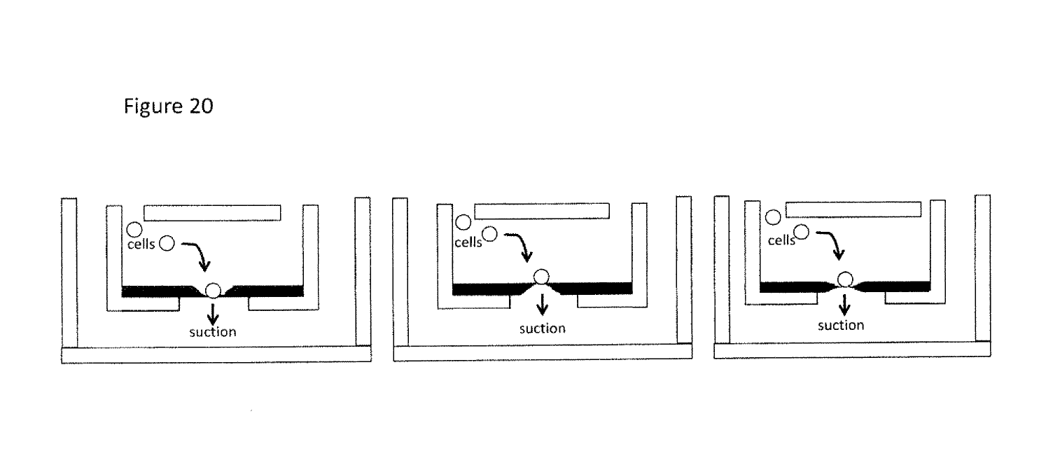

FIG. 20 shows the use of shaped apertures in an automated patch clamp setup to form a gigaohm seal with cells or giant unilamellar vesicles.

Referring to FIG. 1, there is shown known apparatus 2 for forming bilayer lipid membranes from a lipid solution. The apparatus 2 comprises two Teflon chambers 4, 6. The chamber 4 has a wall 8 with a circular aperture 10. The chamber 6 has a wall 12 with a circular aperture 14. Positioned between the two walls 8, 12 is a support layer 16 of a hydrophobic material. The layer 16 has an aperture 18.

The chamber 4 contains a silver/silver chloride electrode 20. The chamber 6 contains a silver/silver chloride electrode 22. The electrode 22 is connected to an amplifier circuit 24 comprising a resistor 26 and an amplifier 28. The circuit 24 has a voltage output line 30 and a voltage command line 32.

FIG. 1b is a cross section through part of the layer 16. A bilayer lipid membrane 34 is shown together with a solvent annulus 36. The aperture 18 has cylindrical sidewalls 38 as shown. The aperture 38 may be from 10-500 μm in diameter. The layer 16 may be from 10-500 μm thick.

In the apparatus 2, the layer 16 is clamped between the two walls 8, 12 of the chambers 4, 6.

FIG. 2 shows a method of fabricating a bilayer lipid membrane. More specifically, FIG. 2 illustrates the use of a Montal-Mueller method (taken from A J Williams 1994). In FIG. 2, it will be seen that support layers 40 are provided with apertures 42. Air and water are deployed as shown. The layers 40 are hydrophobic and they are made from a material such for example as polytetrafluoroethylene. A completed bilayer lipid membrane is shown as bilayer lipid membrane 44.

The formation of a stable bilayer lipid membrane such as the bilayer lipid membrane 44 requires that the hydrophobic support material is a material such as polytetrafluoethylene [Montal-Mueller 1972]. It is also known that the apertures should be from approximately 10-500 μm in diameter, and made in a material with a thickness of from 10-500 μm. The apertures are usually made using methods such as mechanical drilling, laser drilling, or spark discharge. The bilayer lipid membranes are usually fragile, but they can be made more stable by using small diameter apertures, for example not more than 30 microns or having diameters of hundreds of nanometers. However, as mentioned above, this reduction in diameter makes it difficult or impossible to insert proteins into the bilayer lipid membrane.

Large area stable bilayer lipid membranes can be formed if low aspect ratios (ratio thickness of hydrophobic supporting film to aperture diameter) are used [White 1972]. However, this necessitates the use of a very thin support material, which increases the capacitance and noise in the electrical recordings [Wonderlin 1990]. It also makes the entire structure much more difficult to handle and mechanically very fragile. A solution to this problem is the use of tapered sidewall apertures as shown in FIGS. 3a and 3b. FIG. 3a shows an aperture with shaped sidewalls and having a beak-shaped cross section. FIG. 3b shows an aperture with shaped sidewalls and which is triangular in cross section.

In FIGS. 3a and 3b, the aperture is indicated by a line 46. The distance over which shaping is able to be achieved is indicated by a line 48. The distance over which shaping is able to be achieved is variable but it is usually greater than 100 μm. In FIGS. 3a and 3b, the shaped thickness transition region of the aperture is indicated by broken line rings 50.

Shaping the sidewalls of the aperture as shown in FIGS. 3a and 3b permits the use of a thicker support layer. This significantly improves the electrical noise characteristics, and also the mechanical strength of the support layer. The shaped apertures also dramatically increase the ease with which bilayer lipid membranes can be made, and also significantly improves their stability due to the lower aspect ratio of the tip. [Eray et al 1994, Iwata et al 2010, Oshima et al 2012 and USA Patent Publication No. 2012114925A1].

The known fabrication methods for fabricating apertures with shaped sidewalls in a support layer suffer from disadvantages as mentioned above. For example, silicon or silicon nitride have been used, but fabrication of these materials requires expensive and time consuming lithography and etching. Silicon based substrates also produce high intrinsic noise. Shaped apertures can be made in extremely thin polymers [Eray et al 1994] but this necessitates the use of an extra support material. Other methods require a multi-mask fabrication process to manufacture tapered apertures in photoresists. Numerous single masks are used, each of which has to be aligned to the other and to the layers of resist. Multiple separate exposure steps are used, making the manufacturing process long and drawn out. Mask-less direct write lithography techniques such as electron beam lithography, focused ion beam, two photon lithography or laser lithography can also be used to fabricate shaped apertures. Two photon lithographic methods have been used to manufacture shaped apertures in a negative tone resist in the form of SU8 (Kalsi et al. 2014). In this method, a focused beam of light is raster scanned across a surface to cross link resist to different degrees. However, as mentioned above, such an approach is very time intensive and only a single septum can be made in thirteen hours.

FIGS. 4a and 4b illustrate two ways according to the method of the present invention for fabricating at least one aperture with shaped sidewalls in a layer of an ultraviolet sensitive photoresist. More specifically, FIG. 4a shows how the method comprises providing a layer of an ultraviolet sensitive photoresist 54 on a glass substrate 52. A grey scale mask 56 is provided. The mask 56 is positioned above the photoresist 54. Thus the mask 56 controls the intensity of ultraviolet light 58 used to expose the photoresist 54. The mask 56 provides the required shape of a formed aperture 60. As shown in FIG. 4a, the aperture 60 has shaped side walls 62 so that the aperture 60 is hour-glass shaped in cross section.

FIG. 4b shows a similar process which is able to lead to the production of an aperture 64. The aperture 64 has sidewalls 66 which cause the aperture 64 to be generally triangular in cross section. In FIG. 4b, the ultraviolet light 58 illuminates the photoresist 54 through the mask 56 and also through the glass substrate 52. Thus the photoresist 54 is exposed from the bottom in FIG. 4b, and from the top in FIG. 4a where the ultraviolet light 58 does not have to pass through the substrate 52.

The final desired cross sectional shape of the aperture 60, 64 is able to be controlled by encoding the shape in the grey levels of the mask 56. Exposing the photoresist 54 through a mask 56 with different grey levels produces a pseudo three dimensional shaped aperture in a single step as can be appreciated from FIGS. 4a and 4b. For top exposure of the photoresist, then the substrate may be any substrate used in a standard lithographic process and may thus be, for example, a transparent, opaque or absorbent substrate. Exposure from the bottom requires that the substrate 52 is optically transparent.

If the photoresist is a negative tone photoresist, then the negative photoresist can be used as a support material in which a aperture is created. The negative photoresist may be a dry film laminate or it may be liquid solvent based. After exposure, development and baking, the negative photoresist becomes a hard film with excellent mechanical properties. These films do not require any further support materials. The negative photoresist may be TMMF or SU8.

FIG. 5 shows a microscopic image of a pixelated grey scale mask 56 showing four rings representing different grey levels for fabricating shaped apertures such as the apertures 60 or 64. The number of grey scale values can be increased depending upon the smoothness required for each formed shaped aperture. Different grey scale values are able to be obtained by varying the density of pixels (having feature size below the resolution of lithography equipment).

FIG. 6 illustrates by way of example a method of the present invention of fabricating an aperture 68. A substrate 70 is provided as shown at step a. The substrate may be, for example, glass, silicon, silicon nitride, gallium arsenide, sapphire, a polycarbide, a polycarbonate or an olefin polymer. Step 6b illustrates the deposition of a release layer 72 on the substrate 70. The release layer may be less than 1 μm thick. The release layer 72 may be of a material which is dissolved/etched by a chemical to which the photoresist is resistant. The release layer must be transparent to UV or have low absorbance for UV light, for exposure through the substrate (back side exposure). Examples of materials for the release layer are conventional lithographic metals, LOR7B or a transparent sugar/polysaccaride.

FIG. 6c illustrates the step of deposition of a thin layer of photoresist 74. The photoresist 74 may be deposited as a lamination of dry film, or by spin coating of a liquid photoresist. The photoresist may be a dry photoresist or it may be a solvent-based photoresist. The photoresist 74 may be, for example, a TMMF formulation or an SU-8 formulation. Thicknesses of the photoresist 74 can be from 1 μm-1 mm but preferably are from 50-100 μm.

The diameter of the shaped aperture 60,64 may be from 1-200 μm, and is preferably 50-150 μm.

The photoresist 74 may be an unpolymerised photoresist.

FIG. 6d illustrates the exposure of the photoresist 74 with ultraviolet light 76. The exposure is through a grey scale mask 78, and from the top side of the photoresist 74, i.e. from the side of the substrate 70 that contains the photoresist 74. The number of grey scale values on the mask 78 depend on the smoothness required for the shaped sidewalls 80, 82 of the apertures 68.

FIG. 6e shows an alternative to the topside illumination shown in FIG. 6d. In FIG. 6e, the illumination is from the bottom and through the mask 78 and the substrate 70. The top illumination shown in FIG. 6d gives a shaped aperture 68 having side walls 80 as shown in FIG. 6(f1). The bottom illumination of the resist 74 gives an apertures of 68 having the sidewalls 82 shown in FIG. 6(f2).

The method step shown in FIG. 6d or the method step shown in FIG. 6e is followed by a post exposure bake of the photoresist 74, and a development step. As can be appreciated from FIGS. 6(f1) and 6(f2), release of the photoresist 74 from the substrate 70 is effected by dissolving the release layer 72 in an appropriate solution.

In a modification of the method illustrated in FIG. 6, a surface treatment of the photoresist 74 may be effected to make the surface more hydrophobic. This surface treatment may be achieved by depositing a thin layer of parylene using vapour deposition (not more than 500 nm), using spin coating/dip coating Cytop (not more than 100 nm) or Teflon AF, or using a carbon tetrafluoride plasma treatment, or a hydrophobic saline treatment.

In a further modification of the method shown in FIG. 6, the grey scale mask 56 may be replaced by a software mask utilizing digital mirror device technology.

In the method of the invention as illustrated in FIG. 6, a single aperture 68 may be fabricated as shown. Alternatively, an array of apertures may be fabricated.

For use in the formation of the bilayer lipid membrane, the photoresist film can be used without further modification, for example by being clamped between two Teflon or similar material chambers as shown in FIG. 11. After filling the compartment in these chambers with buffer solution, bilayer lipid membranes may be formed using either painting or the Mantel-Mueller method. For the painting method, 2-5 μl of lipid and non-polar solvent suspension are placed on a paintbrush which is moved across the aperture to form the bilayer lipid membrane. For the Montel-Mueller method, the aperture is pretreated with 5% v/v hexadecane in hexane. 5-10 μl of lipid in volatile solvent is placed on top of buffer and solvent is allowed to evaporate for 20-30 minutes to give monolayers on top of the buffer. Raising and lowering of the buffer causes the bilayer lipid membranes to be formed at the aperture. Following successful formation of the bilayer lipid membranes, ion channels or other proteins or peptides may be incorporated into the bilayer lipid membranes.

Referring to FIG. 7, there is shown another method of the present invention. Similar parts as in FIG. 6 have been given the same reference numerals for ease of comparison and understanding. FIG. 7 illustrates a method for fabricating an aperture with shaped sidewalls using a negative tone photoresist 74, but without the release of the photoresist 74 from the substrate 70. Thus FIG. 7 shows shaped aperture 60, 64 formed in photoresist 74 and used for the formation of bilayer lipid membranes without releasing the aperture from the substrate 70.

In FIG. 7a, there is shown the provision of a substrate 70. The substrate 70 may be same substrate as the substrate 70 mentioned above in connection with FIG. 6.

FIG. 7b illustrates the drilling of a hole 84 in the substrate 70 such that the shaped aperture 60, 64, after exposure of the resist 74 lies in the center of the drilled hole 84. The diameter of the hole 84 may be from 1-10 mm and is preferably from 3-7 mm.

FIG. 7c shows the deposition of photoresist 74. The photoresist 74 may be as described above for FIG. 6. The photoresist 74 in FIG. 7 may be 1 μm-1 mm thick and is preferably 50-100 μm thick. The diameter of the shaped aperture 60,64 may be from 1-200 μm, and is preferably 50-150 μm.

FIG. 7d shows topside illumination of the photoresist 74 through a grey scale mask 78, similar to that described above in connection with FIG. 6d. Similarly 7e shows bottom illumination similar to that described above with reference to FIG. 6e.

After exposure of the photoresist, there follows a post-exposure bake of the resist, and a development step.

Modifications mentioned above in connection with FIG. 6 may also be effected for FIG. 7, including the formation of a single aperture or an array of apertures. The photoresist sheets produced benefit from the additional mechanical stability provided by the substrate 70. The photoresist sheets may be used with chambers having slots for receiving the photoresist sheets on substrates as shown in FIG. 12.

FIG. 8 shows a further alternative method of the present invention involving the formation of holes 84 in the substrate 70. FIG. 8 shows schematically the fabrication method for producing a shaped aperture 60 or 64 in negative tone photoresist 74, and without the release of the photoresist 74 from the substrate 70. In FIG. 8, the hole 84 may be formed using, for example a netting process. The method shown in FIG. 8 can be used for the formation of vertical bilayer lipid membranes, using either clamping in between chambers or slotting into chambers as shown in FIG. 12.

FIG. 9 shows another method of the present invention for fabricating an aperture 60 or 64 in a negative tone resist 74 with integrated electrodes for parallel electro physiology and optical accessibility. This method is also able to be used for parallel electro-physiology and optical accessibility. This method is able to be used for parallel electro-physiology with multiple and individual electrically addressable bilayer lipid membranes.

In FIG. 9, there is shown how the shaped apertures 60, 64 are formed in microfluidic chips having integrated electrodes. These devices benefit from multiplex, automated and high throughput formation of bilayer lipid membranes for drug screening.

FIG. 9a shows the provision of a substrate 70. The substrate 70 may be as described above for the substrates referred to in previous Figures.

FIG. 9b shows the patterning of electrodes 86 on the substrate 70. One example of the patterning is gold electrodes, followed by deposition of silver and then chlorination of the electrodes. Other patterning methods for patterning the electrodes may be employed.

FIG. 9c shows the depositing of a first layer of photoresist 74. The deposition of this first layer of photoresist 74 may be as described above in previous Figures. The thickness of the first layer of the photoresist 74 may be 10 μm-1 mm but is preferably 50-100 μm. The diameter of the aperture may be from 100 μm-1 mm but is preferably 200-500 μm. The first layer of the photoresist 74 is patterned to form a bottom cavity for a buffer.

FIG. 9d illustrates the formation of a second layer of the photoresist 74. The second layer of the photoresist 74 may be the same as the first layer of photoresist 74 in terms of material used and thicknesses of the photoresist.

FIG. 9(e1) shows exposure of the two layers of photoresist 74 using ultraviolet light 76 incident from the top and through a grey scale mask 78. The number of grey scale values on the mask 78 depend upon the smoothness required for the shaped sidewall of the aperture 60, 64.

FIG. 9(e2) shows exposure from the bottom side through the substrate 70. Exposure from the bottom side necessitates the use of planar ring electrodes 86 to allow light to pass through.

Exposure is followed by a post exposure bake of the photoresist and a development step.

The process of FIG. 9 may be modified as described above for previous Figures. Thus, for example, the process illustrated in FIG. 9 may be used to fabricate a single aperture or an array of apertures. The photoresist may be given a surface treatment to make it more hydrophobic as described above, for example using the above described examples.

FIG. 10 shows another method of the present invention for fabricating an aperture with shaped sidewalls. FIG. 10 shows schematically the fabrication process for a shaped aperture in negative tone photoresist with integrated electrodes and a flow channel for fluid exchange (in a bottom compartment) for parallel electro physiology and optical accessibility. This platform may be used for parallel electro physiology with multiple and individual electrically accessible bilayers. FIG. 10 thus illustrates another approach for fabricating micro-fluidic devices with integrated electrodes and using shaped apertures. Similar parts as in FIG. 9 have been given the same reference numerals for ease of comparison and understanding. The example of FIG. 10 provides a device in which it is possible to provide for the exchange of solutions on either side of the aperture. Such a device could be used for rapid exchange of the solutions on either side or addition or removal of compounds.

The apertures produced with reference to FIGS. 6, 7 and 8 can be used for bilayer lipid membranes in vertical and horizontal orientation as shown in FIGS. 11a, 11b, 12 and 13.

In FIGS. 11a and 11b, similar parts as in FIGS. 1a and 1b have been given the same reference numerals for ease of comparison and understanding. FIG. 11b also shows an aperture tip 88. In FIG. 11a, there is shown a bilayer lipid membrane set up, where a photoresist sheet 90 is clamped between the two chambers 4, 6. As shown in FIG. 11b, the aperture 18 is shaped in cross section (beak-shaped in this example) and has the bilayer lipid membrane 34.

FIG. 12 shows a photoresist sheet 94 having an aperture 18. The photoresist sheet 94 is on a substrate and able to be slotted into guide slots 95 in a chamber 96. The use of slot-in type chambers 96 enables the formation of a bilayer lipid membrane vertically.

FIG. 13 shows the use of photoresist sheets in a micro fluidic chip and formation of optically accessible horizontal bilayers. Electrodes are not integrated. More specifically, FIG. 13 shows a PMMA top chamber 98 having electrode ports 100. Also shown is a photoresist sheet 102, a PMMA bottom channel 104 and a glass cover slip 106.

FIG. 14 shows the contrast curve, highlighting the photoresist thickness and energy exposure relation, for dry film photoresist TMMF.

FIGS. 15, 16 and 17 show examples of beak and triangular shaped apertures formed in TMMF photoresist using greyscale lithography.

Bilayer lipid membranes formed using shaped apertures such as triangular and beak-shaped apertures are very stable. As a measure of mechanical stability, they can withstand over 50 cycles of raising and lowering the buffer as shown in FIG. 18. Bilayer lipid membrane lifetime with triangular-shaped single and nine bilayers in a 3×3 array apertures (85 μm diameter) is greater than 24 hours using either painting (1:1 DOPC:POPG) or the Montal-Mueller method (DOPC/hexane). Montal-Mueller bilayer lipid membrane in these apertures are very easily formed. FIG. 19 shows the stability of bilayer lipid membranes to aspiration cycles in shaped apertures fabricated using two photon lithography process.

FIG. 20 shows the use of shaped apertures in an automated patch clamp setup for electrical recording from cells or giant vesicles. The diameter of the shaped aperture in this application is 1-20 μm, preferably 1 μm. The device traps the cells or vesicles on to the apertures by applying suction forming a Gigaohm seal with a single cell membrane patch. The patch of the membrane is sucked and whole cell performed using electrodes placed on each side of the aperture.

It is to be appreciated that the embodiments of the invention described above with reference to the accompanying drawings have been given by way of example only and that modifications may be effected. Thus, for example, instead of using ultraviolet light sensitive photoresists, other light sensitive photoresists may be employed. Other light sensitive photopolymers may be employed. Instead of using grey scale masks, software masks using digital mirror device technology may be employed. Individual components shown in the drawings are not limited to use in their drawings and they may be used in other drawings and in all aspects of the invention.

1. A method for fabricating at least one aperture with shaped sidewalls in a layer of a light sensitive photopolymer, which method comprises:
(i) providing the layer of the photopolymer;
(ii) providing a mask;
(i) exposing the photopolymer to light;
(iv) utilising the mask to control the intensity of the light falling on the photopolymer; and
(v) forming the mask such that its control of the intensity of the light falling on the photopolymer causes the aperture to have the shaped sidewalls.

2. A method according to claim 1 in which the mask is a grey scale mask having grey levels, and in which a required shape for the aperture is encoded in the grey levels of the grey scale mask.

3. A method according to claim 1 in which the mask is a software mask, and in which a required shape for the aperture is defined by the software in the software mask.

4. A method according to claim 1 in which the photopolymer is one which hardens when exposed to the light, and in which the photopolymer is a liquid negative photoresist, or a solid laminate sheet negative photoresist.

5. A method according to claim 1 in which the photopolymer is one which weakens or becomes dissolvable after exposure to the light, and in which the photopolymer is a liquid photopolymer, or a solid laminate sheet photopolymer.

6. A method according to claim 1 in which the photopolymer is an unsupported photopolymer.

7. A method according to claim 1 and including providing a substrate as a support for the photopolymer, and providing the photopolymer on the substrate.

8. A method according to claim 7 and including exposing the photopolymer to the light from the side of the photopolymer that is remote from the substrate, and in which the substrate is a transparent substrate, an opaque substrate, or an optically absorbent substrate.

9. A method according to claim 1 and including exposing the photopolymer to the light through the substrate, and in which the substrate is an optically transparent substrate.

10. A method according to claim 1 and including treating the surface of the photopolymer to make the surface of the photopolymer more hydrophobic.

11. A method according to claim 10 in which the treating comprises depositing a layer of parylene using vapour deposition.

12. A method according to claim 10 in which the treating comprises spin coating or dip coating Cytop or Teflon AF.

13. A method according to claim 10 in which the treating comprises a carbon tetrafluoride plasma treatment, or a hydrophobic silane treatment.

14. A method according to claim 1 and comprising forming a bilayer lipid membrane across the aperture.

15. A method according to claim 14 in which the bilayer lipid membrane is clamped between two chambers of a friction reducing material.

16. A method according to claim 15 in which the two chambers have compartments, in which the compartments are filled with a buffer solution, and in which the bilayer lipid membrane is formed using a painting method.

17. A method according to claim 16 in which the painting method comprises placing 2-5 μl of lipid and non-polar solvent suspension on a paintbrush, and moving the paintbrush across the aperture to form the bilayer lipid membrane.

18. A method according to claim 15 in which the two chambers have compartments, in which the compartments are filled with a buffer solution, and in which the bilayer lipid membrane is formed using a Montal-Mueller method.

19. A method according to claim 18 in which the Montal-Mueller method comprises pre-treating the aperture with 5% volume/volume hexadecane in hexane, placing 5-10 μl of lipid in a volatile solvent on top of the buffer, allowing the solvent to evaporate for twenty—thirty minutes to give monolayers on top of the buffer, and raising and lowering the buffer to cause the bilayer lipid membrane to be formed over the aperture.

20. A method according to claim 14 in which proteins and/or peptides are incorporated into the bilayer lipid membrane.
